(19) United States
(12) Patent Application Publication
(10) Pub. No.: US 2013/0009190 A1
(43) Pub. Date: Jan. 10, 2013

(54) LIGHT EMITTING DEVICE AND METHOD FOR MANUFACTURING SAME

(76) Inventor: Yuhichi Memida, Osaka-shi (JP)

(21) Appl. No.: 13/635,959

(22) PCT Filed: Jan. 11, 2011
(86) PCT No.: PCT/JP2011/050232

§ 371 Date: Sep. 19, 2012

(30) Foreign Application Priority Data
Apr. 7, 2010 (JP) 2010-088592

(51) Int. Cl. H01L 33/60

(52) U.S. Cl. 257/98; 438/29; 257/E33.068

(57) ABSTRACT

A light emitting device comprises:
a light emitting element (20);
a first metal board (11) that includes a mount portion (111) on which the light emitting element (20) is mounted and a reflection portion (112) which is formed outside the mount portion (111) to reflect light from the light emitting element (20);
a second metal board (12) that is electrically connected to the light emitting element (20) via a wire (50);
a metal plated layer (15) that is formed on a surface of the metal boards (11), (12); and
a seal resin (40) that is formed on the metal boards (11), (12) to seal at least the light emitting element (20); wherein
at least the reflection portion (112) is provided with a protection layer (35) which is lower than the seal resin (40) in gas permeability, is transparent or has a reflectance near the metal plated layer (15).

### TECHNICAL FIELD

The present invention relates to a light emitting device and a method for manufacturing the light emitting device, more particularly, to a light emitting device including a light emitting element and to a method for manufacturing the light emitting device.

### BACKGROUND ART

A light emitting device using a light emitting diode (LED) has features of low power consumption and long life and the like, and is widely used in various display light sources and the like. Besides, in recent years, a light emitting device using an LED element is finding its wide applications, and needs for a light emitting device which has a high output and a high light emission efficiency are increasing.

On the other hand, when driving a light emitting device at a high output, heat generation from the LED element increases, accordingly, thanks to the heat from the LED element, disadvantages such as decline in light emission efficiency, decline in life and the like occur. Because of this, conventionally, various light emitting devices are proposed, which are able to alleviate the decline in light emission efficiency even in a case of the driving at a high output by radiating the heat from the LED element (e.g., see patent documents 1 to 3).

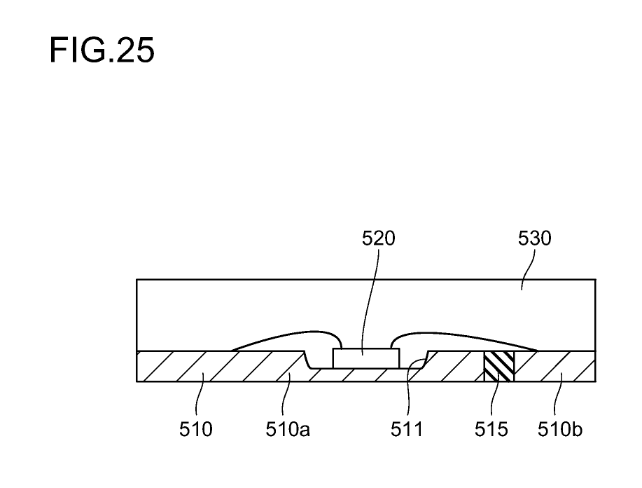

FIG. 25 is a sectional view of a light emitting device as a conventional example described in the patent document 1. Referring to FIG. 25, the light emitting device as the conventional example described in the patent document 1 includes: a board 510 that is formed of a metal material; a light emitting diode chip 520 that is mounted on the board 510; and a light output portion (seal resin) 530 that is disposed on the board 510 to seal the light emitting diode chip 520. The board 510 has a pair of electrode layers 510a and 510b that are insulated by an insulation body 515. On one electrode layer 510a, the light emitting diode chip 520 is mounted. Besides, a dimple portion 511 is disposed on a surface of the electrode layer 510a on which the light emitting diode chip 520 is mounted. The light emitting diode chip 520 is mounted in the dimple portion 511. The dimple portion 511 functions as a reflection structure that reflects light emitted from the light emitting diode chip 520, and increases directivity of the light reflected by the board 510.

In the light emitting device described in the patent document 1, as described above, by mounting the light emitting diode chip 520 on the board 510 formed of a metal material, the heat from the light emitting diode chip 520 is radiated via the board 510 (510a). According to this, temperature rise of the light emitting diode chip 520 is alleviated, accordingly, even in the case of the driving at a high output, the decline in light emission efficiency and the like are alleviated. Besides, by means of the dimple portion 511 that functions as a reflection structure, the light from the light emitting diode chip 520 is effectively output to outside of the package.

Besides, the patent documents 2 and 3 describe light emitting devices that include a heat radiation pad and an LED chip is mounted on the heat radiation pad. In these light emitting devices, the heat from the LED chip generated by the driving is radiated to outside via the heat radiation pad. Besides, in the patent documents 2 and 3, a reflection body (reflection frame body) formed of a resin that has a high reflectance is disposed on the board, and by means of this reflection body, the light from the LED chip is efficiently output. Here, the LED chip is sealed by a seal resin in an inside of the reflection body.

In the light emitting device, to further increase light output efficiency by increasing reflection efficiency on the board, it is general to form a metal plated layer (e.g., a Ag plated layer) made of a metal having a high reflectance on the surface of the board.

Besides, as described above, in the case of driving the light emitting device at a high output, the heat generation from the LED element increases, accordingly, in the light emitting device compatible with the high output, as the seal resin that seals the LED element, a silicone resin, which is excellent in heat resistance and has less deterioration at a high temperature, is used.

### CITATION LIST

### Patent Literature

PLT1: JP-A-2008-42158

PLT2: JP-A-2008-41290

PLT3: JP-A-2008-282932

### SUMMARY OF INVENTION

### Technical Problem

However, the silicone seal resin is used as a very excellent seal resin because of various characteristics such as its high reliability, high optical transparency, producibility and the like, while there is a disadvantage that the silicone seal resin has high gas permeability, which is one of unfavorable characteristics because of a relatively flexible characteristic as measures against stress caused by thermal expansion and the like, and transmits various substances such as moisture content in the air and the like.

Besides, the Ag plated layer does not have a high metal stability, accordingly, thanks to contact with outside air that passes through the silicone seal resin, reacts with moisture content and sulfur content in the air to produce sulfidation, oxidation, chloridation and the like. Because of this, at the surface of the Ag plated layer, disadvantages occur, in which deteriorations (color changes) such as becoming black, becoming brown and the like occur and the reflectance declines. According to this, a problem occurs, in which the light output efficiency declines. In other words, in the light emitting device, the Ag plated layer formed on the surface of the metal board and the reflection frame body formed of the resin are used as the reflection surface; however, compared with the reflection frame body, the color change of the Ag plated layer surface remarkably appears because of a time-dependent change, accordingly, it is conceivable that the color change significantly deteriorates the light output efficiency. Because of this, the present invention alleviates the reflectance deterioration due to the time-dependent change of the metal board surface and prevent the reduction in the light output efficiency.

Here, instead of the Ag plated layer, there is also a method for forming an Au (gold) plated layer, which is excellent in metal stability, on the board surface; however, in this case, the deterioration (color change) of the plated layer is alleviated, but the Au plated layer has a low initial reflectance characteristic compared with the Ag plated layer, accordingly, the light output efficiency declines form an initial stage.

The present invention has been made to solve the problems, and it is an object of the present invention to provide a light emitting device and a method for manufacturing the same that are able to alleviate the decline in the light output efficiency caused by the deterioration of the plated layer.

It is another object of the present invention to provide a light emitting device and a method for manufacturing the same that have an excellent heat radiation characteristic and a high reliability.

It is still another object of the present invention to provide a light emitting device and a method for manufacturing the same that are able to increase yielding.

### Solution to Problem

To achieve the objects, a light emitting device according to a first aspect of the present invention includes: a light emitting element; a first metal board that includes a mount portion on which the light emitting element is mounted and a reflection portion which is formed outside the mount portion to reflect light from the light emitting element; a second metal board that is electrically connected to the light emitting element via a wire; a metal plated layer that is formed on a surface of the first and second metal boards; and a seal resin that is formed on the first and second metal boards to seal at least the light emitting element; wherein at least the reflection portion of the first metal board is provided with a protection layer which is lower than the seal resin in gas permeability, is transparent or has a reflectance near the metal plated layer.

In the light emitting device according to the first aspect, as described above, by forming the protection layer, which is lower than the seal resin in gas permeability, transparent or has the reflectance near the metal plated layer, on at least the reflection portion of the first metal board, it is possible to alleviate the metal plated layer formed on the reflection portion contacting with outside air that passes through the seal resin. On the other hand, the mount portion of the first metal board is covered by the light emitting element, accordingly, it is also possible to alleviate the metal plated layer formed on the mount portion contacting with the outside air that passes through the seal resin. As described above, in the light emitting device according to the first aspect, it is possible to reduce an exposed region (region that contacts with the seal resin) of the metal plated layer, accordingly, it is possible to reduce the region of the metal plated layer that contacts with the outside air that passes through the seal resin. According to this, it is possible to alleviate the deterioration of the metal plated layer (reduce a deterioration region), accordingly, it is possible to alleviate the decline in the light output efficiency caused by deterioration of the metal plated layer.

Besides, in the first aspect, by mounting the light emitting element on the mount portion of the first metal board, it is possible to radiate heat, which is generated by driving the light emitting element, to outside via the metal board that has a high heat conductivity, accordingly, it is possible to alleviate decline in light emission efficiency and decline in life characteristic.

Further, in the first aspect, by forming the metal plated layer on the surfaces of the first and second metal boards, it is possible to reflect light output from a rear side of the light emitting element by means of the metal plated layer formed on the mount portion. Besides, part of the light emitted from the light emitting element is reflected by the protection layer, and in a case of passing through the protection layer, the passing-through light is reflected by the metal plated layer formed on the reflection portion. According to this, it is possible to increase the reflection efficiency on the metal board, accordingly, it is possible to increase the light output efficiency.

Here, as a forming material that forms the protection layer, it is possible to use inorganic materials such as glass and the like and organic materials such as a resin and the like. Besides, it is preferable that the constituent material forming the protection layer is a resin material harder than the seal resin.

In the light emitting device according to the first aspect, preferably, the first and second metal boards have each a step portion that includes an upper surface and a lower surface, and the upper surface of the step portion defines a mount surface on which the light emitting element is mounted and a connection surface to which the wire is connected; and the protection layer made of a resin material is formed on the lower surface of the step portion to cover the metal plated layer. According to this structure, it is possible to protect the metal plated layer on the lower surface portion of the step portion by means of the protection layer, accordingly, it is possible to alleviate the metal plated layer on the lower surface portion of the step portion contacting with the outside air that passes through the seal resin. According to this, it is possible to alleviate the metal plated layer on the lower surface portion of the step portion deteriorating. Besides, by mounting the light emitting element on the upper surface (mount surface) of the step portion, it is possible to radiate the heat generated by driving the light emitting element to the outside via the metal board that has the high heat conductivity. In addition, it is possible to alleviate the area of the metal board decreasing, accordingly, it is possible to secure sufficient heat conduction. According to this, it is possible to efficiently radiate the heat from the light emitting element. As a result of this, even in the case of this structure, it is possible to alleviate the decline in the light emission efficiency and the decline in the life characteristic. Here, it is preferable that by forming the step portion, the lower surface of the step portion is formed to define the reflection portion.

In the light emitting device according to the first aspect, preferably, the protection layer is formed of a white resin. According to this structure, the white resin is unlikely to transmit outside air (low in gas permeability), accordingly, it is possible to effectively alleviate the deterioration of the metal plated layer. Besides, the white resin also has a high reflectance, accordingly, it is possible to increase the reflection efficiency on the metal board and effectively increase the light output efficiency.

In the light emitting device according to the first aspect, preferably, the mount portion includes the mount surface on which the light emitting element is mounted; and the mount surface has an area equal to a bottom area of the light emitting element or an area smaller than the bottom area of the light emitting element. According to this structure, it is possible to more effectively reduce the exposed region (region that contacts with the seal resin) of the metal plated layer, accordingly, it is possible to more effectively alleviate the deterioration of the metal plated layer (reduce the deterioration region).

In the light emitting device according to the first aspect, the first and second metal boards may be provided with a reflection frame body that has a reflection surface to reflect the light from the light emitting element. In this case, it is preferable that the reflection frame body and the protection layer are each formed of the white resin.

In the light emitting device according to the first aspect, it is preferable that the protection layer is formed of a thermosetting white resin.

In this case, it is preferable that the thermosetting white resin is formed of a silicone resin. The silicone thermosetting white resin is unlikely to transmit outside air, and besides a high reflectance, is unlikely to deteriorate (change color) in the presence of heat and light, accordingly, by forming the protection layer by means of this white resin, it is possible to obtain a light emitting device that is able to keep high light emission efficiency (reflection efficiency) even in a long-time use. Here, in a case of forming the reflection frame body in the metal board, like the protection layer, it is also preferable to form the reflection frame body by means of the silicone thermosetting white resin.

In the light emitting device according to the first aspect, it is preferable that the first metal board has an area larger than the second metal board. According to this structure, it is possible to effectively radiate the heat from the light emitting element to the outside via the first metal board that has the large area.

A method for manufacturing a light emitting device according to a second aspect of the present invention includes: a process for forming a metal frame that include a first metal board that has a mount portion on which a light emitting element is mounted and a second metal board that is electrically connected to the light emitting element; a process for forming a step portion on a predetermined region of the metal frame; a process for forming a metal plated layer on a surface of the metal frame; a process for forming a reflection frame body whose inner surface defines a reflection surface; a process for mounting the light emitting element on the metal frame in a frame of the frame body; a process for electrically connecting the light emitting element to the second metal board via a wire; and a process for injecting a seal resin into the frame of the frame body to seal the light emitting element and the wire; wherein the process for forming the step portion includes a process for forming the step portion on the first metal board and the second metal board such that an upper surface of the step portion defines a mount surface on which the light emitting element is mounted and a connection surface to which the wire is connected; and the process for forming the reflection frame body includes a process for forming the reflection frame body by means of a white resin, and a process for forming, by means of the white resin, a protection layer that covers the metal plated layer which is formed on a lower surface of the step portion.

In the method for manufacturing a light emitting device according to the second aspect, as described above, by forming the reflection frame body and the protection layer by means of the white resin in the same process, it is possible to alleviate an increase in production processes and produce a light emitting device that has a stable shape. According to this, it is possible to increase yielding and reduce a production cost (product cost).

In the method for manufacturing a light emitting device according to the second aspect, preferably, the process for forming the step portion includes a process for selectively removing, by means of etching, a predetermined region of the first metal board and the second metal board such that the upper surface of the step portion defines the mount surface on which the light emitting element is mounted and the connection surface to which the wire is connected. According to this structure, it is possible to easily form the step portion on the metal frame (metal board).

In the method for manufacturing a light emitting device according to the second aspect, the process for forming the step portion may be structured to include a process for pressing the metal frame such that the upper surface of the step portion defines the mount surface on which the light emitting element is mounted and the connection surface to which the wire is connected.

In the method for manufacturing a light emitting device according to the second aspect, it is preferable that the process for forming the step portion includes a process for forming the step portion on the predetermined region of the metal frame such that the mount surface has an area identical to a bottom area of the light emitting element or an area smaller than the bottom area of the light emitting element.

In the method for manufacturing a light emitting device according to the second aspect, the process for forming the reflection frame body includes a process for forming the reflection frame body and the protection layer by means of a thermosetting silicone resin. According to this structure, it is possible to easily produce a light emitting device that has a high light emission efficiency and a high reliability.

### Advantageous Effects of Invention

As described above, according to the present invention, it is possible to easily obtain a light emitting device and a method for manufacturing the same that are able to alleviate the decline in the light output efficiency caused by the deterioration of the plated layer.

Besides, according to the present invention, it is possible to easily obtain a light emitting device and a method for manufacturing the same that have an excellent heat radiation characteristic and a high reliability.

Further, according to the present invention, it is possible to easily obtain a light emitting device and a method for manufacturing the same that are able to increase the yielding.

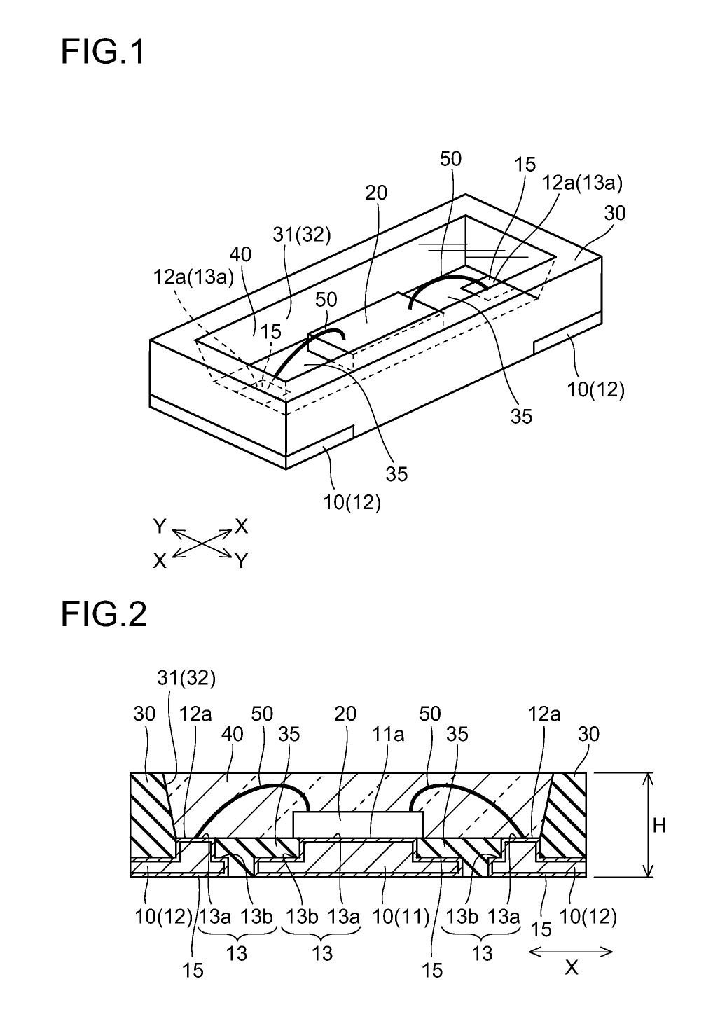

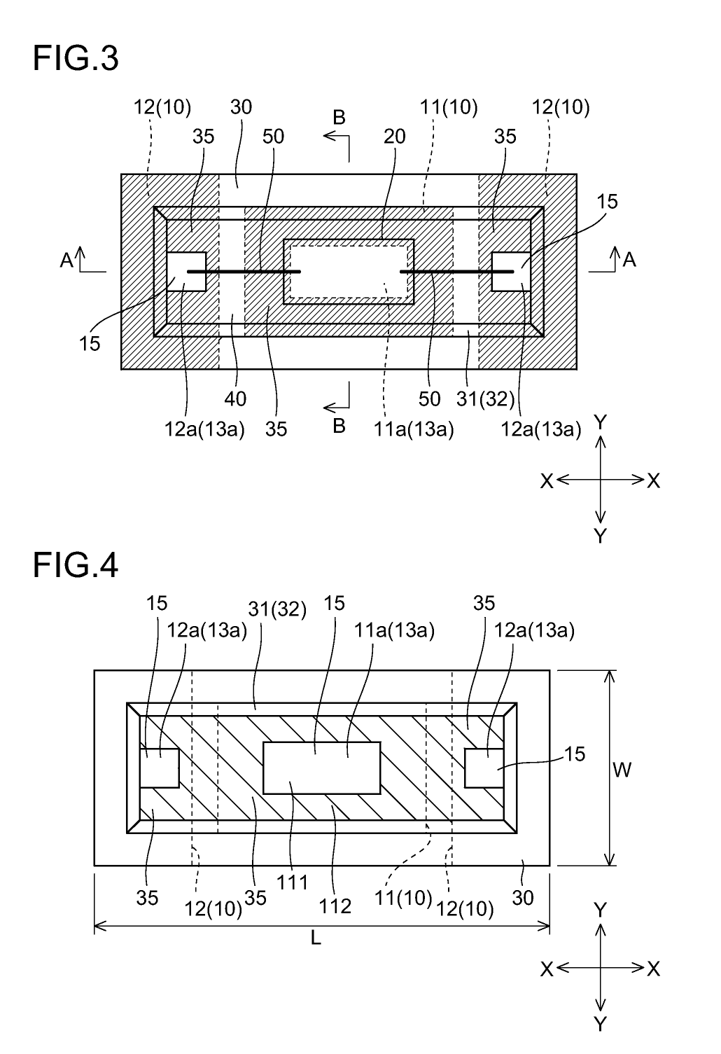

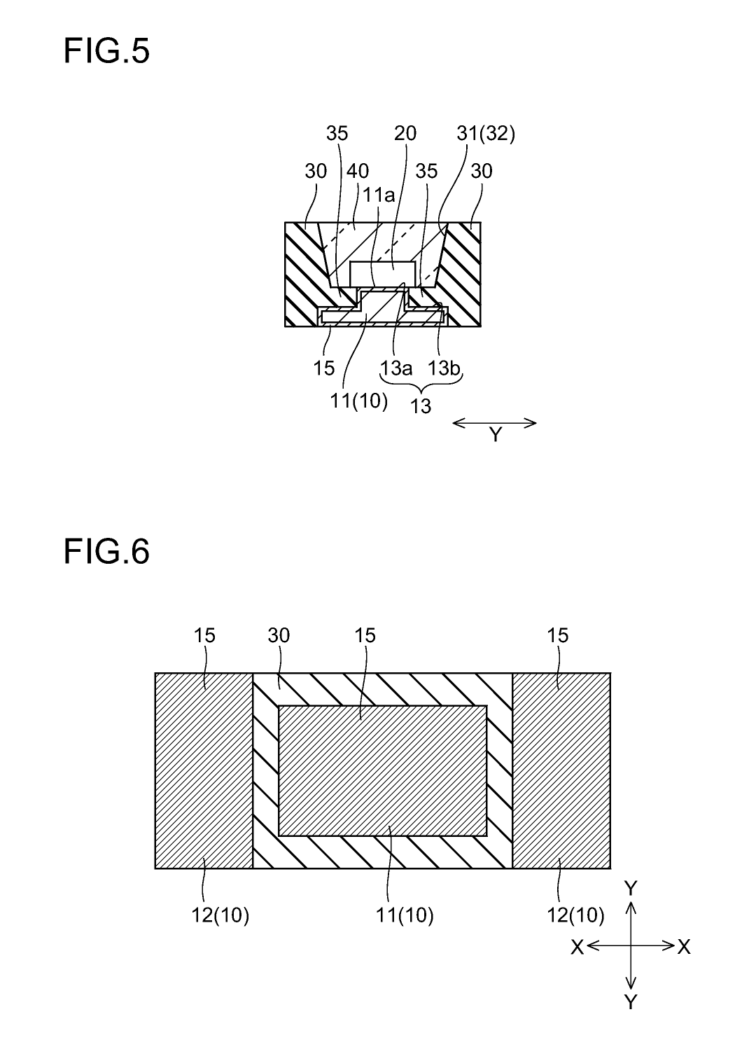

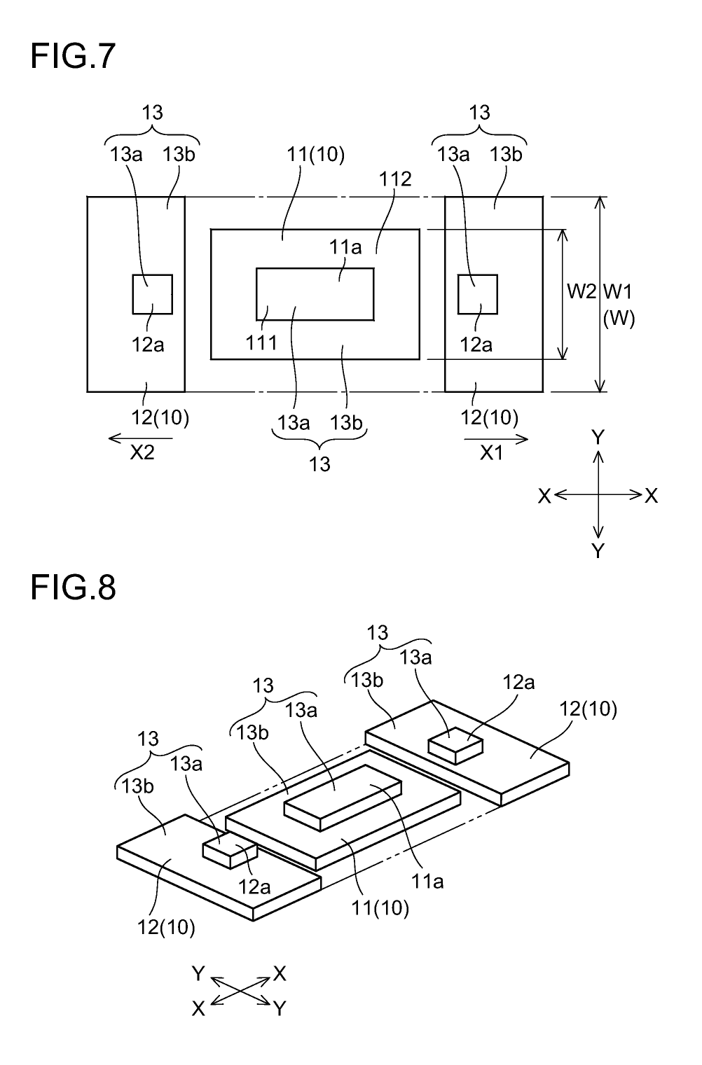

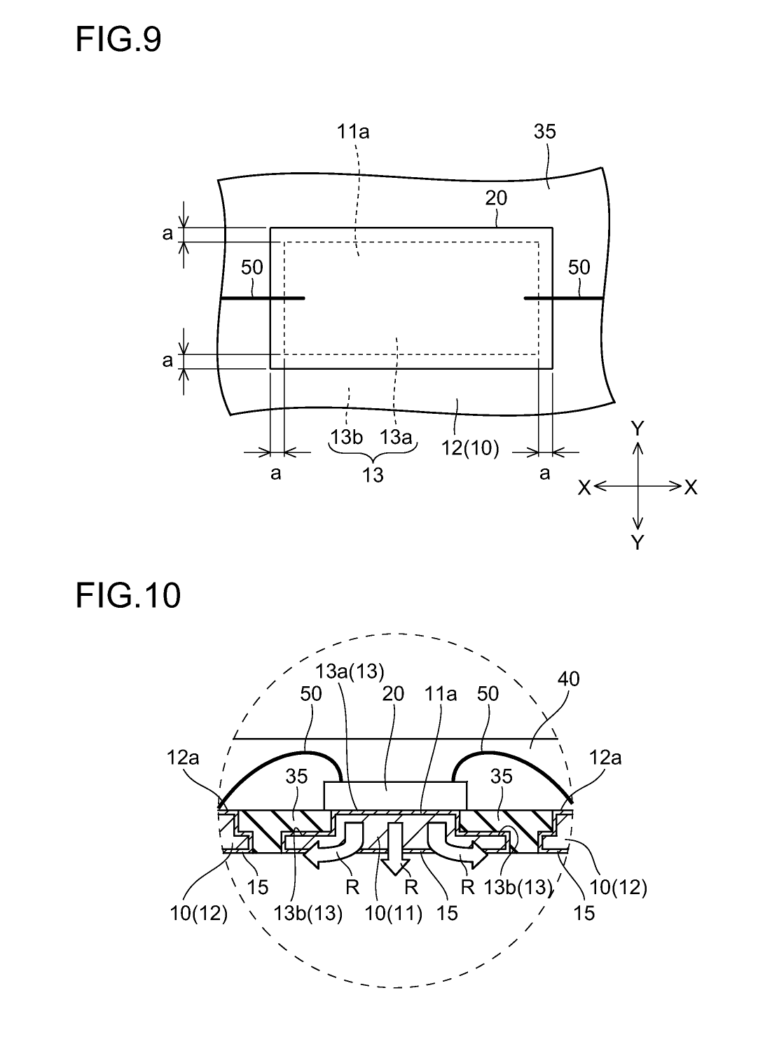

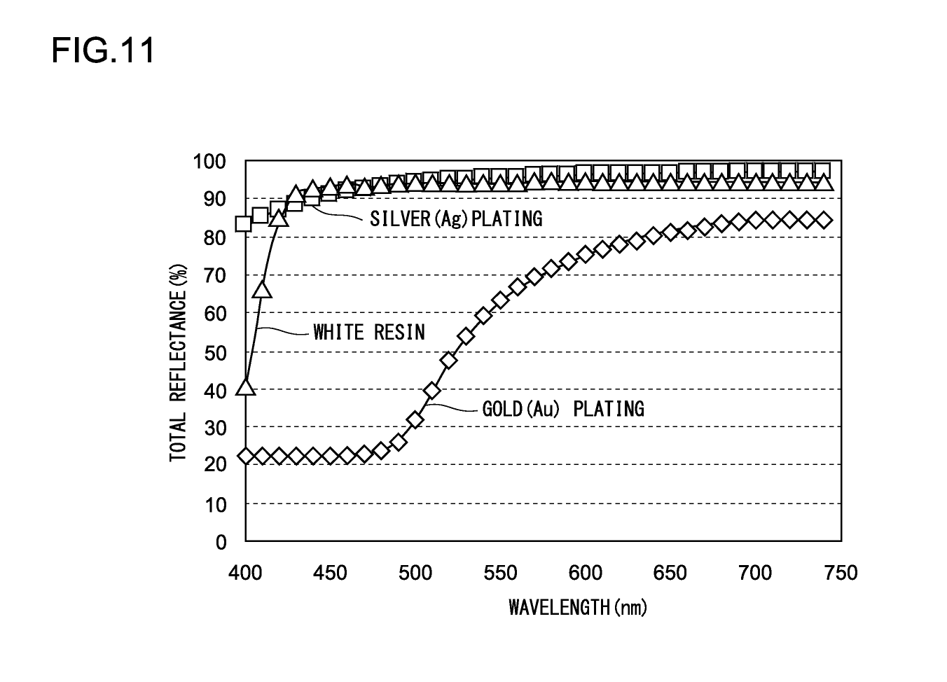

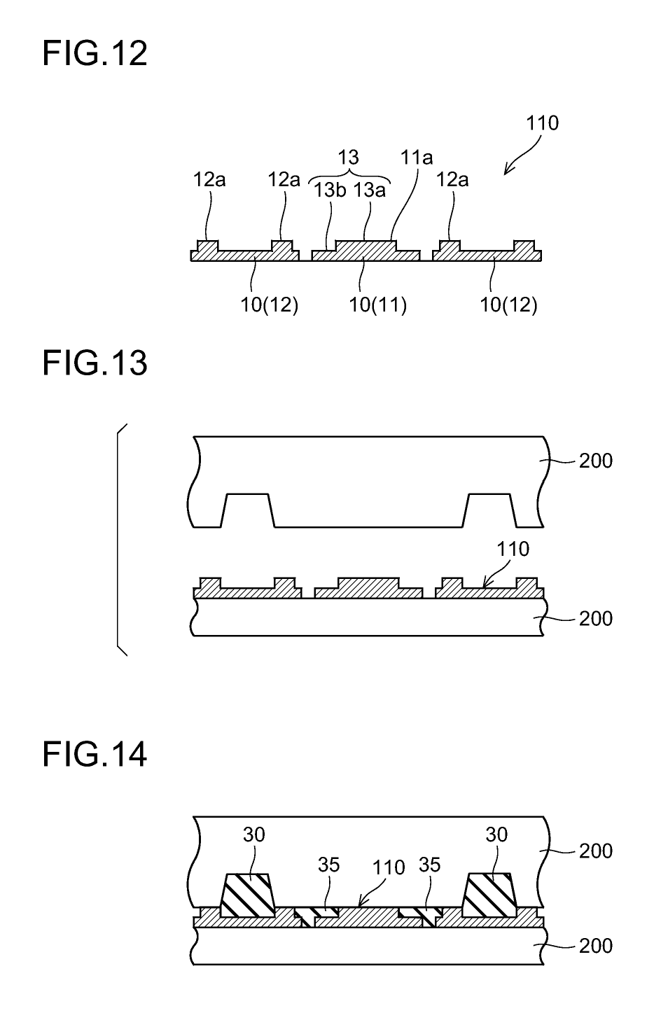

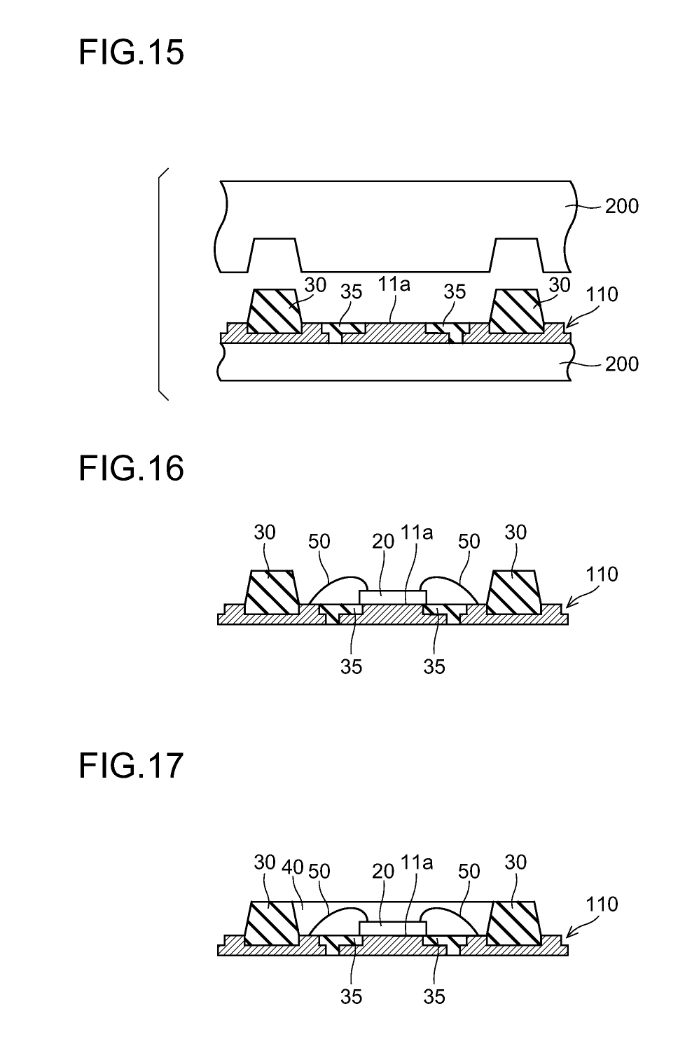

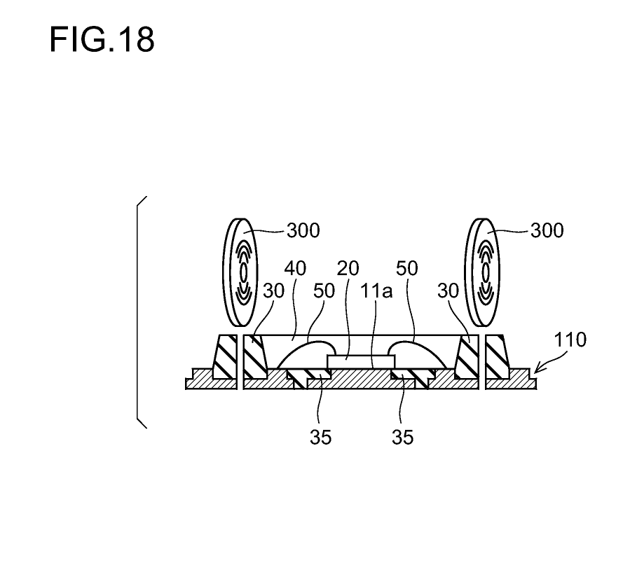

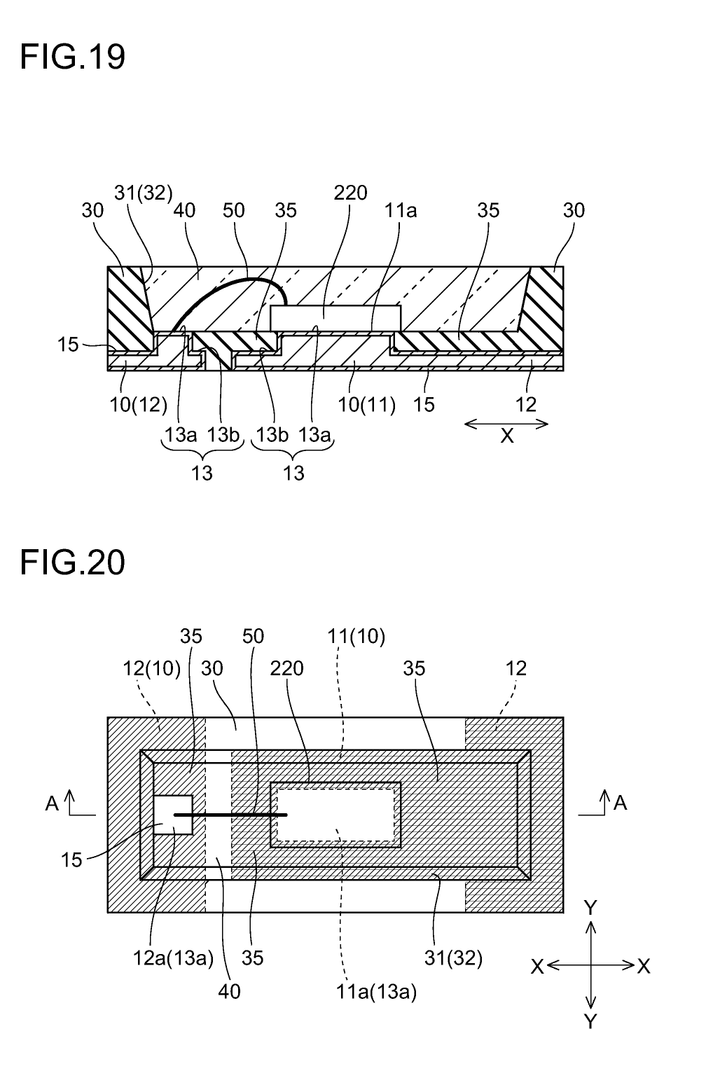

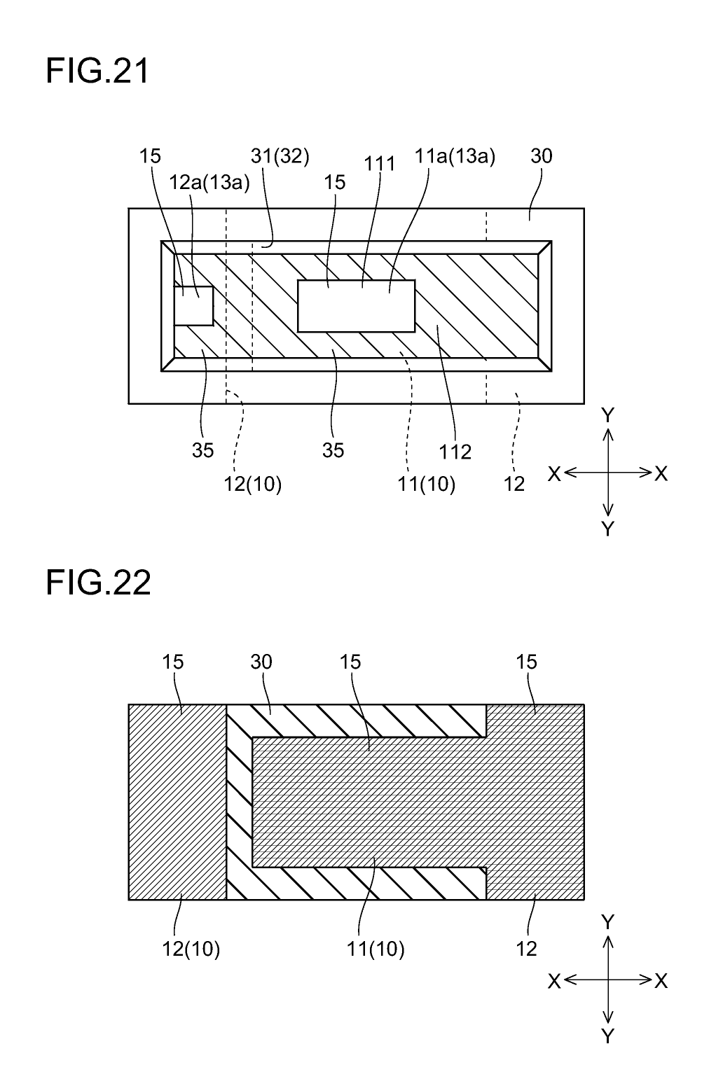

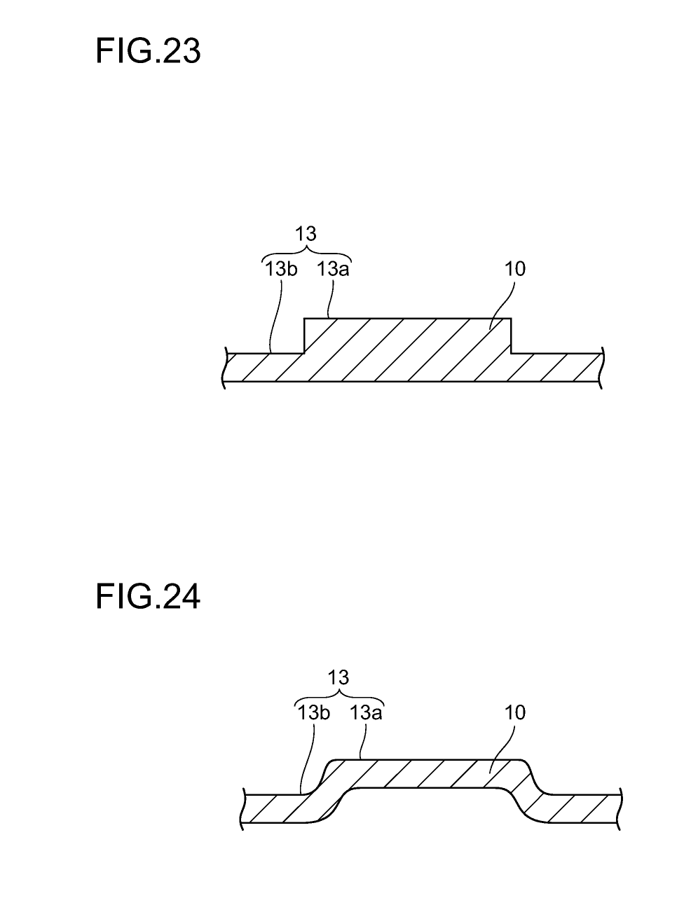

### BRIEF DESCRIPTION OF DRAWINGS

[FIG. 1] is an overall perspective view of a light emitting device according to a first embodiment of the present invention.

[FIG. 2] is a sectional view (view corresponding to a cross section along an A-A line in FIG. 3) of a light emitting device according to a first embodiment of the present invention.

[FIG. 3] is a plan view of a light emitting device according to a first embodiment of the present invention.

[FIG. 4] is a plan view (view showing a state in which an LED chip, a wire and a seal member are removed) of a light emitting device according to a first embodiment of the present invention.

[FIG. 5] is a sectional view (view corresponding to a cross section along a B-B line in FIG. 3) of a light emitting device according to a first embodiment of the present invention.

[FIG. 6] is a plan view (view of a state when seeing a light emitting device from a rear side) of the light emitting device according to a first embodiment of the present invention. [FIG. 7] is a plan view for describing a metal board of a light emitting device according to a first embodiment of the present invention.

[FIG. 8] is a perspective view for describing a metal board of a light emitting device according to a first embodiment of the present invention.

[FIG. 9] is a plan view (view showing an enlarged portion of FIG. 3) of a light emitting device according to a first embodiment of the present invention.

[FIG. 10] is a sectional view showing an enlarged portion of a light emitting device according to a first embodiment of the present invention.

[FIG. 11] is a view showing an example of an initial reflectance characteristic of silver plating, gold plating and a white resin.

[FIG. 12] is a sectional view for describing a method for manufacturing a light emitting device according to a first embodiment of the present invention.

[FIG. 13] is a sectional view for describing a method for manufacturing a light emitting device according to a first embodiment of the present invention.

[FIG. 14] is a sectional view for describing a method for manufacturing a light emitting device according to a first embodiment of the present invention.

[FIG. 15] is a sectional view for describing a method for manufacturing a light emitting device according to a first embodiment of the present invention.

[FIG. 16] is a sectional view for describing a method for manufacturing a light emitting device according to a first embodiment of the present invention.

[FIG. 17] is a sectional view for describing a method for manufacturing a light emitting device according to a first embodiment of the present invention.

[FIG. 18] is a sectional view for describing a method for manufacturing a light emitting device according to a first embodiment of the present invention.

[FIG. 19] is a sectional view (view corresponding to a cross section along an A-A line in FIG. 20) of a light emitting device according to a second embodiment of the present invention.

[FIG. 20] is a plan view of a light emitting device according to a second embodiment of the present invention.

[FIG. 21] is a plan view (view showing a state in which an LED chip, a wire and a seal member are removed) of a light emitting device according to a second embodiment of the present invention.

[FIG. 22] is a plan view (view of a state when seeing a light emitting device from a bottom side) of the light emitting device according to a second embodiment of the present invention.

[FIG. 23] is a sectional view showing a portion of a metal board of a light emitting device according to a first modification of the present invention.

[FIG. 24] is a sectional view showing a portion of a metal board of a light emitting device according to a second modification of the present invention.

[FIG. 25] is a sectional view of a light emitting device according to a conventional example described in a patent document 1.

### DESCRIPTION OF EMBODIMENTS

Hereinafter, embodiments realizing the present invention are described in detail based on the drawings. Here, in the following embodiments, an example is described, in which the present invention is applied to a light emitting device of one chip type in which one LED chip is mounted.

### First Embodiment

FIG. 1 is an overall perspective view of a light emitting device according to a first embodiment of the present invention. FIG. 2 is a sectional view of the light emitting device according to the first embodiment of the present invention. FIG. 3 is a plan view of the light emitting device according to the first embodiment of the present invention. FIG. 4 to FIG. 11 are a plan view for describing the light emitting device according to the first embodiment of the present invention. Here, FIG. 4 shows a state in which an LED chip, a wire and a seal member are removed. First, with reference to FIG. 1 to FIG. 11, a structure of the light emitting device according to the first embodiment of the present invention is described.

The light emitting device according to the first embodiment includes an LED of surface mount type, and is structured to emit white light (pseudo-white light). Specifically, the light emitting device according to the first embodiment, as shown in FIG. 1 to FIG. 3, includes: a metal board 10; a light emitting diode chip (LED chip) 20 that is mounted on the metal board 10; a reflection frame body 30 that is disposed to cover a portion of the metal board 10; and a seal member 40 that seals the LED chip 20. Here, the LED chip 20 is an example of a “light emitting element” of the present invention, and the seal member 40 is an example of a “seal resin” of the present invention.

Besides, the light emitting device according to the first embodiment, as shown in FIG. 3 and FIG. 4, is formed to be substantially a rectangle when seeing from top. The size (package size) of the light emitting device is formed such that a length L in a long direction (X direction) is about 1.0 mm to about 6.0 mm (e.g., about 3.5 mm); a length W in a short direction (Y direction) is about 1.0 mm to about 6.0 mm (e.g., about 1.5 mm); a height H (see FIG. 2) is about 0.3 mm to about 1.2 mm (e.g., about 1 mm) Here, although not shown in the first embodiment, as for a general size (package size) of a light emitting device, a quadrangular shape, which includes edges each having a length of about 1.0 mm to about 6.0 mm, is often used; the height is often formed to be about 0.3 mm to about 1.2 mm; and irrespective of the size, it is possible to employ the same structure as the first embodiment.

The metal board 10 is formed of a metal material (e.g., copper or copper alloy) that has a high heat conductivity. The metal board 10, as shown in FIG. 2, has: a first metal board 11 on which the LED chip 20 is mounted; and a pair of second metal boards 12 that function as electrode terminals for electric power supply. Besides, as shown in FIG. 7 and FIG. 8, the pair of second metal boards 12 are each insulated from the first metal board 11, and disposed to sandwich the first metal board 11 when seeing from top. Specifically, one of the pair of second metal boards 12 is disposed to one end side (X1 side) of the first metal board 11 in the long direction (X direction), while the other one of the pair of second metal boards 12 is disposed to the other end side (X2 side) of the first metal board 11 in the long direction (X direction). Here, the one of the pair of second metal boards 12 functions as an anode electrode or a cathode electrode, while the other one of the pair of second metal boards 12 functions as a cathode electrode or an anode electrode.

Besides, the first metal board 11 is formed to include: a mount portion 111 on which the LED chip 20 (see FIG. 2) is mounted; and a reflection portion 112 that is disposed outside the mount portion 111 to reflect light from the LED chip 20.

Besides, a length W2 of the first metal board 11 in the Y direction is formed to be smaller than a length W1 (W) of the second metal board 12 in the Y direction. And, a reflection frame body 30 is disposed to cover a side surface of the first metal board 11. According to this, it becomes possible to increase the mechanical strength of the package. Besides, the metal board 10 is formed by cutting away a predetermined portion of a metal frame. Here, the metal board 10 before the cutting away is connected to the metal frame by means of a not-shown connection portion.

Here, in the first embodiment, the first metal board 11 of the metal board 10 is formed to have an area larger than each of the second metal board 12.

Besides, in the first embodiment, a step portion 13 having an upper surface 13a and a lower surface 13b is formed on a surface (upper surface) of the metal board 10. The step portion 13 is formed on each of the first metal board 11 and the second metal board 12, and the upper surface 13a of the step portion 13 of the first metal board 11 defines the mount surface 11a on which the LED chip 20 (see FIG. 2) is mounted. Besides, the upper surface 13a of the step portion 13 of the second metal board 12 defines a connection surface 12a to which a later-described wire is connected.

Further, in the first embodiment, as shown in FIG. 3 and FIG. 9, the mount surface 11a of the metal board 10 is formed to have an area smaller than a bottom surface of the LED chip 20. In other words, the mount surface 11a is formed to be a size (shape) that the LED chip 20 is able to cover when the LED chip 20 is mounted. Specifically, the mount surface 11a has substantially a rectangle when seeing from top, and the length of each edge is formed to be shorter than the LED chip 20.

Here, in the first embodiment, the upper surface 13a of the step portion 13 of the first metal board 11 corresponds to the mount surface 111, while the lower surface 13b of the step portion 13 of the first metal board 11 corresponds to the reflection portion 112. Besides, the lower surface 13b (portion situated in an opening portion 31 of the reflection frame body 30) of the step portion 13 of the second metal board 12 also functions as a reflection portion that reflects reflected light from the LED chip 20.

Here, in a case of considering heat conduction to the metal board 10, it is preferable that a contact area between the LED chip 20 and the mount surface 11a is as large as possible. Because of this, in a case of considering a mount error, it is preferable that the area of the mount surface 11a is set at the largest possible size that the LED chip 20 is able to cover. Specifically, as shown in FIG. 9, it is preferable that the mount surface 11a is formed to be shorter than each edge of the LED chip 20 by a distance a (e.g., about 20 μm to about 100 μm). In other words, it is preferable that when the LED chip 20 is mounted, the mount surface 11a is disposed inside from each edge (each side) of the LED chip 20 by the distance a.

Besides, in a case of mounting the LED chip 20 by using a surface mounter and the like, considering mount accuracy, it is preferable to form the size of the mount surface 11a that the LED chip 20 is surely able to cover. For example, under the actual situation, the surface mounter has a mount position error of about 100 μm, accordingly, it is preferable that the length of each edge of the mount surface 11a is formed to be shorter than the LED chip 20 by about 200 μm; in the future, thanks to higher accuracy of the surface mounter, it is also possible to achieve further size reduction (area equal to the LED chip).

Besides, it is preferable that the connection surface 12a of the metal board 10 is formed to be an as small area as possible in a range where wire bonding is possible. In a case where a wire is connected by using a wire bonding apparatus, considering an error (accuracy) and the like of the apparatus, it is possible to form the area of the connection surface 12a to be a square with an edge of about 200 μm to about 300 μm. However, the shape of the connection surface 12a is not limited to a quadrangle, and it is possible to use various shapes such as a circle, an ellipse, a trapezoid and the like.

Besides, in the first embodiment, the metal board 10 has a thickness of, for example, about 200 μm to about 300 μm (e.g., about 270 μm), and a height difference between the upper surface 13a and the lower surface 13b of the step portion 13 is set at about 100 μm, for example. Here, it is preferable that the height difference of the step portion 13 is about 60% of the thickness of the metal board 10.

Further, in the first embodiment, an Ag plated layer 15 is formed on the entire surface of the metal board 10. Here, the Ag plated layer 15 is an example of a “metal plated layer” of the present invention.

The reflection frame body 30 is formed of a high-reflectance white resin to efficiently reflect the light from the LED chip 20. Besides, as shown in FIG. 1, FIG. 2 and FIG. 5, the reflection frame body 30 is fixed to an upper side of the metal board 10, and provided with the opening portion 31 that has a depth in the thickness direction which reaches the surface (upper surface) of the metal board 10. A side surface (inner circumferential surface) of the opening portion 31 defines a reflection surface 32 that reflects the light from the LED chip 20, and to efficiently output the light upward, an opening width of the opening portion 31 is formed in a tapered manner to become wider upward. Besides, as shown in FIG. 4, the reflection frame body 30 is formed such that the mount surface 11a and the connection surface 12a of the metal body 10 are situated in the opening portion 31.

Besides, in the first embodiment, as shown in FIG. 2, on the lower surface 13b of the step portion 13, a protection layer 35 made of the same white resin as the reflection frame body 30 is formed. This protection layer 35 is formed to cover the Ag plated layer 15 on the lower surface 13b of the step portion 13, and the upper surface (upper surface of the protection layer 35) is formed to be substantially coplanar (flush surface) with the mount surface 11a and the connection surface 12a. Because of this, the bottom surface of the opening portion 31 of the reflection frame body 30 is a flat surface. Besides, the thickness of the protection layer 35 is formed to be the same size (e.g., about 100 μm) as the height difference of the step portion 13. In other words, the protection layer 35 is formed to be a relatively thin thickness through which the light from the LED chip 20 is able to pass. Further, the reflection frame body 30 is formed to cover the side surface of the first metal board 11 of the metal board 10.

In the light emitting device having this structure according to the first embodiment, as shown in FIG. 4, in the opening portion 31 of the reflection frame body 30, the mount surface 11a and the connection surface 12a are exposed, and a region (hatched region) other than the mount surface 11a and the connection surface 12a is a region covered by the white resin.

Besides, as shown in FIG. 6, in a rear side of the light emitting device, a rear surface (Ag plated layer 15) of the metal board 10 (first metal board 11 and second metal board 12) is exposed, and a circumference of the first metal board 11 is enclosed by the reflection frame body 30 (white resin).

Here, the above white resin is a material forming the package (reflection frame body and the like), and is a resin that has a package shape, fixes the metal board (metal frame), further efficiently reflects the light emitted from the LED chip to play a role in performing efficient light output to outside of the package.

The white resin used for the reflection frame body 30 and the protection layer 35 may be a thermoplastic resin material that is generally used for a package of an LED light emitting device, however, more preferably, a thermosetting resin material. Besides, it is more preferable to form the reflection frame body 30 and the protection layer 35 by using a silicone thermosetting white resin that is one of the thermosetting white resins. As the thermosetting white resin, it is possible to use a material described in, for example, JP-A-2010-31269 and the like. Bedsides, as the silicone thermosetting white resin, it is possible to use materials described in, for example, JP-A-2010-18786, JP-A-2010-21533, JP-A-2009-221393 and the like. Further, for example, it is also possible to use a thermosetting silicone mold resin (reflector (reflection material) material of the “SWC series” used for a high-brightness LED announced by Shin-Etsu Chemical Co., Ltd. on Sep. 10, 2009) from Shin-Etsu Chemical Co., Ltd.

This white resin, as shown in FIG. 11, has an initial reflectance characteristic that is substantially the same as the Ag plating. Especially, among the white resins, resins (e.g., a silicone thermosetting white resin and the like) are found, which do not change in reflectance at all even if they are left for 2000 hours under an environment of 150° C. Because of this, according to this characteristic, it is expected that the reflectance does not change so much even if the resins are left for more than thousands of hours.

The LED chip 20 is formed of a nitride semiconductor that emits (radiates) blue light or near ultraviolet light thanks to power supply. The LED chip 20 has a chip size of about 600 μm×about 240 μm, for example. Here, the LED chip 20 has a chip size larger than the mount surface 11a, and is mounted on the metal board 10 in the opening portion 31 of the reflection frame body 30 via an adhesion layer (not shown) and the like. Specifically, the LED chip 20 is mounted on the mount surface 11a disposed in the opening portion 31 of the reflection frame body 30 to cover the mount surface 11a.

The LED chip 20 mounted on the metal board 10, as shown in FIG. 2, is electrically connected to the connection surface 12a of the second metal board 12 via a wire 50. Here, as the wire 50, it is possible to use, for example, a metal thin wire such as a gold wire and the like that has a size of 25 μm to 30 μm in diameter.

The seal member 40 is formed of a transparent resin material (seal material) that has optical transparency. Specifically, in the first embodiment, the seal member 40 is formed of a silicone resin (silicone seal material) that is excellent in heat resistance and has less deterioration at a high temperature, and is disposed in the opening portion 31 of the reflection frame body 30 to seal the LED chip 20 and the wire 50.

Besides, the seal member 40 contains fluorescer (e.g., YAG fluorescer) particles that apply wavelength conversion to the blue light or near ultraviolet light emitted from the LED chip 20. According to this, a structure is employed such that the light emitted from the light emitting device turns into white light.

Here, the seal member 40 formed of the silicone resin has a relatively flexible characteristic as measures against stress such as thermal expansion and the like. In contrast to this, the protection layer 35 formed of the white resin is harder than the seal member 40 and has a characteristic that is unlikely to transmit outside air (low in gas permeability).

Besides, in the light emitting device according to the first embodiment, as shown in FIG. 10, the heat generated by driving is radiated to outside via the first metal board 11 of the metal board 10. In the metal board 10 (first metal board 11), thanks to the forming of the step portion 13, the sectional area of the first metal board 11 is slightly reduced; however, the surface area of the first metal board 11 does not reduce, accordingly, the first metal board 11 (metal material) is expanded into the white resin around the LED chip 20. Because of this, sufficient heat conduction is secured, accordingly, the heat from the LED chip 20 is efficiently radiated to the outside. Here, in FIG. 10, heat conduction routes are schematically shown by arrows R.

Besides, the light emitted from the LED chip 20 is directly output to the outside and also output from a rear side of the LED chip 20. The light output from the rear side of the LED chip 20 is efficiently reflected by the Ag plated layer 15 formed on the mount surface 11a. Besides, the light is efficiently reflected by the protection layer 35 (white resin) formed around the LED chip 20, and light passing through the thin protection layer 35 is efficiently reflected by the Ag plated layer 15 under the protection layer 35. In this way, in the light emitting device according to the first embodiment, a high reflectance is obtained as a whole.

In the first embodiment, as described above, by forming the protection layer 35, which is lower than the seal member 40 in gas permeability and has a reflectance near the Ag plated layer 15, on at least the reflection portion 112 of the first metal board 11, it is possible to alleviate the Ag plated layer 15 formed on the reflection portion 112 contacting with outside air that passes through the seal member 40. On the other hand, the mount portion 111 (mount surface 11a) of the first metal board 11 is covered by the LED chip 20, accordingly, it is also possible to alleviate the Ag plated layer 15 formed on the mount portion 111 (mount surface 11a) contacting with the outside air that passes through the seal member 40. In this way, in the light emitting device according to the first embodiment, it is possible to reduce an exposed region (region that contacts with the seal member 40) of the Ag plated layer 15, accordingly, it is possible to reduce a region of the Ag plated layer 15 that contacts with the outside air that passes through the seal member 40. According to this, it is possible to alleviate (reduce a deterioration region) deterioration of the Ag plated layer 15, accordingly, it is possible to alleviate deterioration of light output efficiency caused by the deterioration of the Ag plated layer 15.

Besides, in the first embodiment, by forming the step portion 13 on the metal board 10 and forming the protection layer 35 formed of the white resin on the lower surface 13b of the step portion 13, it is possible to protect the Ag plated layer 15 on the lower surface portion (reflection portion 112) of the step portion 13 by the protection layer 35. Because of this, it is possible to alleviate the Ag plated layer 15 on the lower surface portion of the step portion 13 contacting with the outside air that passes through the seal member 40, accordingly, it is possible to alleviate the Ag plated layer 15 on the lower surface portion of the step portion 13 deteriorating. Besides, by mounting the LED chip 20 on the upper surface (mount surface 11a) of the step portion 13, it is possible to radiate the heat generated by driving the LED chip 20 to the outside via the metal board 10 (first metal board 11) that has the high heat conductivity.

Besides, in the first embodiment, by forming the step portion 13 on the metal board 10 and mounting the LED chip 20 on the upper surface 13a (mount surface 11a) of the step portion 13, it is possible to radiate the heat generated by driving the LED chip 20 to the outside via the metal board 10 (first metal board 11) that has the high heat conductivity. In addition, it is possible to alleviate the area of the metal board 10 reducing, it is possible to secure sufficient heat conduction. According to this, it is possible to efficiently radiate the heat from the LED chip 20. In other words, it is possible to obtain an excellent heat radiation characteristic. As a result of this, it is possible to alleviate decline in light emission efficiency and decline in life characteristic.

Further, in the first embodiment, by forming the Ag plated layer 15 on the surface of the metal board 10, it is possible to efficiently reflect the light output from the rear side of the LED chip 20 by means of the Ag plated layer 15 formed on the mount surface 11a (mount portion 111). Besides, part of the light emitted from the LED chip 20 is reflected by the protection layer 35 formed of the white resin that has the high reflectance. Further, the protection layer 35 is formed to be a thin film of about 100 μm, accordingly, the protection layer 35 transmits partial light. And, the partial light passing through the protection layer 35 is reflected by the Ag plated layer 15 formed on the lower surface 13b of the step portion 13. According to this, it is possible to increase reflection efficiency on the metal board 10, accordingly, it is possible to increase the light output efficiency.

Here, instead of the Ag plated layer 15, it is possible to employ a method for forming an Au (gold) plated layer excellent in metal stability on the surface of the metal board 10; however, in this case, deterioration (color change) of the plated layer is alleviated, but, as shown in FIG. 11, the gold (Au) plated layer has a low initial reflectance characteristic compared with the silver (Ag) plating, accordingly, the light output efficiency declines from an initial stage. Because of this, as the metal plated layer formed on the metal board 10, the Ag plated layer is more preferable than the Au plated layer. Besides, by employing the structure, even in the case where the Ag plated layer is formed, it is possible to alleviate the deterioration (color change) of the plated layer.

Besides, in the first embodiment, by forming the mount surface 11a of the LED chip 20 to have an area smaller than a bottom area of the LED chip 20, it is possible to cover the Ag plated layer 15 of the mount surface 11a by means of the LED chip 20, accordingly, it is possible to effectively reduce the exposed region (region that contacts with the seal member 40) of the Ag plated layer 15. According to this, it is possible to more effectively alleviate (reduce the deterioration region) the deterioration of the Ag plated layer 15.

Besides, in the first embodiment, in a case where the thermosetting white resin or the thermosetting silicone white resin is used as the white resin that forms the protection layer 35 and the reflection frame body 30, it is possible to alleviate the deterioration (color change) of the protection layer 35 and the reflection frame body 30 in the presence of heat and light. In other words, the white resin is unlikely to transmit outside air, high in reflectance, besides, unlikely to deteriorate (change color) in the presence of heat and light. Because of this, by forming the protection layer 35 and the reflection frame body 30 by using the white resin, it is possible to obtain a light emitting device that is able to keep a high light emission efficiency (reflection efficiency) even in long-time use.

Besides, in the first embodiment, by forming the first metal board 11 of the metal board 10 to have the area larger than each of the second metal boards 12 of the metal board 10, it is possible to effectively radiate the heat from the LED chip 20 to the outside via the first metal board 11 that has the large area.

Further, in the first embodiment, by forming the protection layer 35 such that the upper surface (upper surface of the protection layer 35) becomes substantially coplanar (flush surface) with the mount surface 11a and the connection surface 12a, it is possible to increase the reflection efficiency on the board and increase more effectively the light output efficiency.

FIG. 12 to FIG. 18 are sectional views for describing a method for manufacturing the light emitting device according to the first embodiment of the present invention. Next, with reference to FIG. 2, FIG. 7, FIG. 8, and FIG. 12 to FIG. 18, the method for manufacturing the light emitting device according to the first embodiment of the present invention is described.

First, as shown in FIG. 12, by applying pressing (punching) and etching to a metal plate (e.g., a copper plate or a copper alloy plate) that has a predetermined thickness, a metal frame 110 is formed. The forming of the metal plate 110 is performed to include a plurality of the metal boards 10, and each of the plurality of the metal boards 10 is formed to include the first metal board 11 and the second metal board 12 that is away from the first metal board 11 by a predetermined distance.

Next, by applying half etching to the metal frame 110, a predetermined region of the metal frame 110 is selectively removed, and the step portion 13 is formed on the predetermined region of the metal frame 110. According to this, the metal frame 110 having a convex structure in section is obtained. At this time, as shown in FIG. 7 and FIG. 8, the upper surface 13a of the step portion 13 is formed to define the mount surface 11a on which the LED chip 20 (see FIG. 2) is mounted and the connection surface 12a to which the wire 50 (see FIG. 2) is connected. Besides, as described above, the mount surface 11a is formed to have an area smaller than the bottom area of the LED chip 20.

Next, the Ag plated layer 15 (see FIG. 2) is formed on the entire surface of the metal frame 110 on which the step portion 13 is formed.

Next, by using a transfer molding method, a compression molding method and the like, the reflection frame body 30 (see FIG. 2) is integrally formed with the metal frame 110. Specifically, first, as shown in FIG. 13, the metal frame 110 is placed on a metal mold 200. Next, as shown in FIG. 14, after performing the mold closing, the white resin is injected. And, the injected resin is set. According to this, the reflection frame body 30 made of the white resin is formed, and the protection layer 35 made of the white resin is formed on the lower surface 13b of the step portion 13.

Thereafter, as shown in FIG. 15, the mold opening is performed, and the metal frame 110 provided with the reflection frame body 30 is taken out.

Next, as shown in FIG. 16, after mounting the LED chip 20 on the mount surface 11a, wire bonding is performed. Next, as shown in FIG. 17, after injecting the silicone seal resin into the inside of the reflection frame body 30, the seal resin is set. According to this, the seal member 40 for sealing the LED chip 20 and the wire 50 is disposed in the inside of the reflection frame body 30. Finally, as shown in FIG. 18, by using a dicing saw 300 and the like, the metal frame 110, on which the reflection frame body 30 is disposed, is cut into separate light emitting devices. In this way, the light emitting device according to the first embodiment is produced.

In the method for manufacturing the light emitting device according to the first embodiment, as described above, by using the white resin, the reflection frame body 30 and the protection layer 35 are formed in the same process, whereby it is possible to alleviate production processes increasing. In addition, it is possible to produce a light emitting device that has a stable shape. According to this, it is possible to increase the yielding and reduce the production cost (product cost).

Besides, in the first embodiment, by selectively removing the predetermined region of the metal frame 110 by means of the half etching, it is possible to easily form the step portion 13 on the predetermined region of the metal frame 110. Besides, it is possible to easily form the upper surface 13a of the step portion 13 to define the mount surface 11a on which the LED chip 20 is mounted and the connection surface 12a to which the wire 50 is connected.

Besides, in the first embodiment, when forming the reflection frame body 30, it is preferable to form the reflection frame body 30 and the protection layer 35 by means of a thermosetting silicone resin. By forming the reflection frame body 30 and the protection layer 35 by means of this white resin, it is possible to produce a light emitting device that is able to keep high light emission efficiency (reflection efficiency) even in long-time use.

### Second Embodiment

FIG. 19 is a sectional view according to a second embodiment of the present invention. FIG. 20 and FIG. 21 are plan views of the light emitting device according to the second embodiment of the present invention when seeing from top. FIG. 22 is a plan view of the light emitting device according to the second embodiment of the present invention when seeing from bottom. FIG. 21 shows a state in which the LED chip, the wire and the seal member are removed. Next, with reference to FIG. 19 to FIG. 22, the light emitting device according to the second embodiment of the present invention is described. Here, in each drawing, corresponding constituent elements are indicated by the same reference numbers, whereby double description is skipped.

The light emitting device according to the second embodiment, as shown in

FIG. 19 and FIG. 20, is formed to be a surface mount LED of one wire type. Specifically, in the second embodiment, unlike the first embodiment, an LED chip 220, in which an electrode is formed on both of an upper surface and a lower surface (rear surface), is mounted on the mount surface 11a (mount portion 111) of the metal board 10. Besides, the LED chip 220 is mounted on the mount surface 11a, whereby the LED chip 220 and the mount surface 11a are electrically connected to each other.

Besides, in the second embodiment, as shown in FIG. 19, FIG. 20 and FIG. 22, like in the structure of the first embodiment, the first metal board 11 and one of the second metal boards 12 are integrally connected to each other. Because of this, as shown in FIG. 20 and FIG. 21, the connection surface 12a electrically connected to the wire 50 is formed on only the other one of the second metal boards 12 that is separated from the first metal board 11. According to this, the exposed region (region that contacts with the seal member 40) of the Ag plated layer 15 is smaller than the first embodiment.

Accordingly, in the second embodiment, it becomes possible to more alleviate the deterioration of the Ag plated layer 15 (reduce the deterioration region), accordingly, it is possible to more alleviate the decline in the light output efficiency caused by the deterioration of the Ag plated layer 15.

Other effects of the second embodiment are the same as the first embodiment.

It should be considered that the embodiments disclosed this time are examples in all respects and are not limiting. The scope of the present invention is not indicated by the description of the embodiments but by the claims, and all modifications within the scope of the claims and the meaning equivalent to the claims are covered.

For example, in the first and second embodiments, the example is described, in which the present invention is applied to the light emitting device of one chip type in which one LED chip is mounted; however, the present invention is not limited to this, and the present invention is also applicable to a light emitting device in which a plurality of LED chips are mounted.

Besides, in the first and second embodiments, the example is described, in which the light emitting device is formed to emit the pseudo-white light by means of the combination of the nitride semiconductor LED chip and the fluorescer; however, the present invention is not limited to this, and a structure may be employed, in which LED chips for respectively emitting R (red) light, G (green) light, and B (blue) light of the three primary colors are mounted and the white light is output by emitting all the light at the same time.

Here, in the first and second embodiments, it is possible to form the light emitting device to allow emission of color light other than the white light.

Besides, in the first and second embodiments, the example is described, in which the light emitting device (package shape) is formed to be substantially the rectangle; however, the present invention is not limited to this, and the light emitting device (package shape) may be formed to be another shape (package shape) other than the rectangle. For example, the light emitting device may be formed to be a square shape (package shape).

Besides, in the first and second embodiments, the example is described, in which the step portion is formed on the metal board; however, the present invention is not limited to this, and a structure may be employed, in which the step portion is not formed on the metal board.

Besides, in the first and second embodiments, the example is described, in which the reflection frame body and the protection layer are formed of the same white resin; however, the present invention is not limited to this, and the reflection frame body and the protection layer may be formed of different materials. Here, it is preferable that the protection layer has hardness with which it is possible to form the package (reflection frame body).

Besides, in the first and second embodiments, the example is described, in which the protection layer is formed by means of the white resin; however, the present invention is not limited to this, and it is also possible to form the protection layer by means of a material other than the white resin. For example, it is also possible to form the protection layer by means of glass and the like. As the material to form the protection layer, it is preferable to use a material that has a high reflectance, is unlikely to transmit outside air (low in gas permeability), and unlikely to deteriorate (change color) in the use environment (temperature and light) of the light emitting device. Here, it is sayable that a material harder than the seal resin for forming the seal member is a material which is more unlikely to transmit outside air (low in gas permeability) than the seal member.

Besides, in the first and second embodiments, the color of the protection layer may be a color other than the white or may be transparent. In a case of transparent, it is possible to reflect the light by means of the metal plated layer under the protection layer, accordingly, it is possible to obtain a high reflectance.

Besides, in the case where the protection layer is formed by means of the white resin, as described above, it is preferable to use a thermosetting white resin or a thermosetting silicone white resin. In a case where the protection layer is formed of the thermosetting white resin or the thermosetting silicone white resin, it is possible to alleviate the protection layer deteriorating (changing color) in the presence of heat and light during a driving time of the light emitting device, accordingly, it is possible to keep the high light emission efficiency (reflection efficiency) for a long time. Here, as the thermosetting white resin and the thermosetting silicone white resin, a material other than the material described above may be used. In addition, besides the silicone white resin, for example, an epoxy thermosetting white resin or an acrylic thermosetting resin may be used. Further, in the future, if a material, which has a high reflectance, is unlikely to transmit outside air (low in gas permeability), and unlikely to deteriorate (change color) in the use environment (temperature and light) of the light emitting device, is developed, it is also possible to form the protection layer by means of such a material.

Besides, in the first and second embodiments, the example is described, in which the Ag plated layer as an example of the metal plated layer is formed on the metal board surface; however, the present invention is not limited to this, and a metal plated layer other than the Ag plated layer may be formed on the metal board surface. For example, a rhodium plated layer, an aluminum plated layer, a palladium plated layer, a platinum plated layer or the like may be formed on the metal board surface. Of course, it is also possible to form a gold plated layer. However, in a case of forming a gold plated layer, the initial reflectance characteristic declines compared with the case of forming the Ag plated layer and the like, it is preferable to form a plated layer other than the metal plated layer.

Besides, in the first and second embodiments, the example is described, in which the step portion is formed on the surface of the metal board by means of the etching (half etching); however, the present invention is not limited to this, and the step portion may be formed by a method other than the etching. For example, the step portion may be formed on the surface of the metal board by means of a pressing method and the like. In a case of forming the step portion by means of the pressing method, it is possible to form the step portion 13 to be a shape as shown in FIG. 23, and it is also possible to form the step portion 13 to be a shape as shown in FIG. 24. However, in a case of the shape shown in FIG. 24, when the LED chip is mounted on the upper surface 13a of the step portion 13, the portion on which the LED chip is mounted is away from the outer contact surface (heat conduction portion), accordingly, the heat radiation characteristic declines. Because of this, in the case where the step portion is formed by means of the pressing method, it is preferable to form the shape as sown in FIG. 23.

Besides, in the first and second embodiments, the example is described, in which the mount surface of the metal board is formed to have the area smaller than the bottom surface of the LED chip; however, it is more preferable that the mount surface of the metal board has the same area (same shape) as the bottom surface of the LED chip. Here, the mount surface of the metal board may be somewhat larger than the bottom surface of the LED chip; however, if it becomes too large, the region of the plated layer, which is not covered by the LED chip to be exposed, becomes large. Because of this, it is preferable to set the size of the mount surface such that the exposed region of the plated layer becomes as small as possible.

Besides, in the first and second embodiments, the example is described, in which the mount surface of the metal board is formed to be substantially the rectangle; however, the present invention is not limited to this, and the mount surface may be a shape other than the rectangle. For example, it is possible to use various shapes such as a circle, an ellipse, a trapezoid and the like.

Here, in the first and second embodiments, it is possible to suitably change the chip size of the LED chip, the package size of the light emitting device, the shape and dimension of the metal board, the height difference of the step portion and the like.

Besides, in the first and second embodiments, the example is described, in which the upper surface of the protection layer is formed to be substantially coplanar (flush surface) with the mount surface and the connection surface; however, the present invention is not limited to this, and the upper surface of the protection layer may not be coplanar (flush surface) with the mount surface and the connection surface.

Besides, in the first and second embodiments, the example is described, in which by means of the dicing saw and the like, the separate light emitting devices are formed; however, the present invention is not limited to this, and a plurality of the light emitting devices may be used with connected to one another without forming the separate light emitting devices.

### REFERENCE SIGNS LIST

10 metal board
11 first metal board
11a mount surface
111 mount portion
112 reflection portion
12 first metal board
12a connection surface
13 step portion
13a upper surface of step portion
13b lower surface of step portion
15 Ag plated layer (metal plated layer)
20, 220 LED chips (light emitting elements)
30 reflection frame body
31 opening portion
32 reflection surface
35 protection layer
40 seal member (seal resin)
50 wire
110 metal frame
200 metal mold
300 dicing saw

1. A light emitting device comprising:
a light emitting element;
a first metal board that includes a mount portion on which the light emitting element is mounted and a reflection portion which is formed outside the mount portion to reflect light from the light emitting element;
a second metal board that is electrically connected to the light emitting element via a wire;
a metal plated layer that is formed on a surface of the first and second metal boards; and
a seal resin that is formed on the first and second metal boards to seal at least the light emitting element; wherein
at least the reflection portion of the first metal board is provided with a protection layer which is lower than the seal resin in gas permeability, is transparent or has a reflectance near the metal plated layer.

2. The light emitting device according to claim 1, wherein
the first and second metal boards have each a step portion that includes an upper surface and a lower surface, and the upper surface of the step portion defines a mount surface on which the light emitting element is mounted and a connection surface to which the wire is connected; and
the protection layer made of a resin material is formed on the lower surface of the step portion to cover the metal plated layer.

3. The light emitting device according to claim 1, wherein
the protection layer is formed of a white resin.

4. The light emitting device according to claim 1, wherein
the mount portion includes the mount surface on which the light emitting element is mounted; and
the mount surface has an area equal to a bottom area of the light emitting element or an area smaller than the bottom area of the light emitting element.

5. The light emitting device according to claim 1, wherein
the first and second metal boards are provided with a reflection frame body that has a reflection surface to reflect the light from the light emitting element; and
the reflection frame body and the protection layer are each formed of the white resin.

6. The light emitting device according to claim 1, wherein
the protection layer is formed of a thermosetting white resin.

7. The light emitting device according to claim 6, wherein
the thermosetting white resin is formed of a silicone resin.

8. The light emitting device according to claim 1, wherein
the first metal board has an area larger than the second metal board.

9. A method for manufacturing a light emitting device comprising:
a process for forming a metal frame that include a first metal board that has a mount portion on which a light emitting element is mounted and a second metal board that is electrically connected to the light emitting element;
a process for forming a step portion on a predetermined region of the metal frame;
a process for forming a metal plated layer on a surface of the metal frame;
a process for forming a reflection frame body whose inner surface defines a reflection surface;
a process for mounting the light emitting element on the metal frame in a frame of the frame body;
a process for electrically connecting the light emitting element to the second metal board via a wire; and
a process for injecting a seal resin into the frame of the frame body to seal the light emitting element and the wire; wherein
the process for forming the step portion includes a process for forming the step portion on the first metal board and the second metal board such that an upper surface of the step portion defines a mount surface on which the light emitting element is mounted and a connection surface to which the wire is connected; and
the process for forming the reflection frame body includes a process for forming the reflection frame body by means of a white resin, and a process for forming, by means of the white resin, a protection layer that covers the metal plated layer which is formed on a lower surface of the step portion.

10. The method for manufacturing a light emitting device according to claim 9, wherein
the process for forming the step portion includes a process for selectively removing, by means of etching, a predetermined region of the first metal board and the second metal board such that the upper surface of the step portion defines the mount surface on which the light emitting element is mounted and the connection surface to which the wire is connected.

11. The method for manufacturing a light emitting device according to claim 9, wherein
the process for forming the step portion includes a process for pressing the metal frame such that the upper surface of the step portion defines the mount surface on which the light emitting element is mounted and the connection surface to which the wire is connected.

12. The method for manufacturing a light emitting device according to claim 9, wherein
the process for forming the step portion includes a process for forming the step portion on the predetermined region of the metal frame such that the mount surface has an area identical to a bottom area of the light emitting element or an area smaller than the bottom area of the light emitting element.

13. The method for manufacturing a light emitting device according to claim 9, wherein
the process for forming the reflection frame body includes a process for forming the reflection frame body and the protection layer by means of a thermosetting silicone resin.
